(19) United States
(12) Patent Application Publication
(10) Pub. No.: US 2026/0342350 A1
(43) Pub. Date: Oct. 29, 2026

(54) ANALOG-TO-DIGITAL CONVERSION CIRCUIT FOR HIGH-SPEED OPERATION, OPERATING METHOD OF ANALOG-TO-DIGITAL CONVERSION CIRCUIT, AND ELECTRONIC DEVICE

(71) Applicant: SAMSUNG ELECTRONICS CO., LTD., Suwon-si (KR)

(72) Inventors: Hojin KIM, Suwon-si (KR); Jeongjin ROH, Seoul (KR); Jihun CHOI, Seoul (KR); Taehun KIM, Seoul (KR); Kyunghoon LEE, Suwon-si (KR); Woongtaek LIM, Suwon-si (KR); Michael CHOI, Suwon-si (KR)

(73) Assignees: SAMSUNG ELECTRONICS CO., LTD., Suwon-si (KR); IUCF-HYU (INDUSTRY-UNIVERSITY COOPERATION FOUNDATION HANYANG UNIVERSITY), Seoul (KR)

(21) Appl. No.: 19/661,171

(22) Filed: Apr. 28, 2026

(30) Foreign Application Priority Data
Apr. 29, 2025 (KR) 10-2025-0056745

(51) Int. Cl. H03M 1/38; H03M 1/12; H03M 1/36

(52) U.S. Cl. CPC H03M 1/38; H03M 1/126; H03M 1/361

(57) ABSTRACT

According to an aspect of the present disclosure, an analog-to-digital conversion circuit for performing an analog-to-digital conversion on an input signal to generate an output signal includes a loop filter, a flash-analog-to-digital converter (flash-ADC), and a first successive approximation register-ADC (SAR-ADC). The loop filter is configured to perform oversampling on a first analog signal corresponding to the input signal to generate a second analog signal. The flash-ADC is configured to sample the second analog signal based on a first clock signal having a first sampling frequency, and determine N high-order bits from among a plurality of bits corresponding to the sampled second analog signal. The first SAR-ADC is configured to sample the second analog signal based on a second clock signal having a second sampling frequency, and determine M low-order bits corresponding to remaining bits excluding the N high-order bits from among the plurality of bits.

### CROSS-REFERENCE TO RELATED APPLICATIONS

This application claims priority under 35 U.S.C. § 119 to Korean Patent Application No. 10-2025-0056745, filed on Apr. 29, 2025, in the Korean Intellectual Property Office, the disclosure of which is incorporated by reference herein in its entirety.

### BACKGROUND

### 1. Field

The present disclosure relates to an analog-to-digital conversion circuits, and more particularly, to an analog-to-digital conversion circuit that performs a high-speed and high-resolution conversion operation based on a time-interleaving method, an operating method of the analog-to-digital conversion, and an electronic device.

### 2. Description of Related Art

Demand for high-speed and/or high-resolution analog-to-digital conversion circuits for various electronic devices may have continued to increase. To convert analog signals into digital signals at a relatively high speed, a plurality of analog-to-digital conversion circuits may include a plurality of analog-to-digital converters, and the plurality of analog-to-digital converters may be controlled in a time-interleaving manner.

Mismatches, such as, but not limited to, an offset mismatch, a gain mismatch, or a timing skew mismatch, may occur between a plurality of analog-to-digital converters controlled in the time-interleaving manner, which may degrade performance in the analog-to-digital conversion circuits. Attempts to compensate for these mismatches may include a calibration circuit. However, the calibration circuit may increase the area of analog-to-digital conversion circuits and/or may cause additional power consumption. Therefore, there exists a need for further improvements in analog-to-digital conversion technology, as the need for high-speed and/or high-resolution analog-to-digital conversion operations may be constrained by a need for a calibration circuit. Improvements are presented herein. These improvements may also be applicable to other signal processing technologies.

### SUMMARY

One or more example embodiments of the present disclosure provide an analog-to-digital conversion circuit capable of calibrating mismatch that may occur between a plurality of analog-to-digital converters controlled in a time-interleaving manner without a calibration circuit and performing a high-speed, high-resolution analog-to-digital conversion operation, an operating method of the analog-to-digital conversion circuit, and an electronic device.

The technical aspects of the present disclosure are not limited to the technical aspects mentioned above, and other technical aspects not mentioned may be clearly understood by those skilled in the art from the description below.

According to an aspect of the present disclosure, an analog-to-digital conversion circuit for performing an analog-to-digital conversion on an input signal to generate an output signal includes a loop filter, a flash-analog-to-digital converter (flash-ADC), and a first successive approximation register-ADC (SAR-ADC). The loop filter is configured to perform oversampling on a first analog signal corresponding to the input signal to generate a second analog signal. The flash-ADC is configured to sample the second analog signal based on a first clock signal having a first sampling frequency, and determine N high-order bits from among a plurality of bits corresponding to the sampled second analog signal. The first SAR-ADC is configured to sample the second analog signal based on a second clock signal having a second sampling frequency, and determine M low-order bits corresponding to remaining bits excluding the N high-order bits from among the plurality of bits corresponding to the sampled second analog signal. The output signal corresponding to the first analog signal is generated based on the N high-order bits and the M low-order bits. N is a first positive integer greater than or equal to 1, and M is a second positive integer greater than or equal to 1.

According to an aspect of the present disclosure, an operating method of an analog-to-digital conversion circuit for performing an analog-to-digital conversion on an input analog signal to generate an output digital signal includes performing oversampling on a first analog signal corresponding to the input analog signal to generate a second analog signal, sampling the second analog signal based on a first clock signal having a first sampling frequency, determining N high-order bits by performing the analog-to-digital conversion on the sampled second analog signal, sampling the second analog signal based on a second clock signal having a second sampling frequency, determining M low-order bits by performing the analog-to-digital conversion on the sampled second analog signal, and outputting the output digital signal including the N high-order bits and the M low-order bits. N is a first positive integer greater than or equal to 1, and M is a second positive integer greater than or equal to 1.

According to an aspect of the present disclosure, an electronic device for performing an analog-to-digital conversion on an input signal to generate an output signal includes a clock signal generation circuit and an analog-to-digital conversion circuit. The clock signal generation circuit is configured to generate a first clock signal having a first sampling frequency and a second clock signal having a second sampling frequency. The analog-to-digital conversion circuit is configured to perform oversampling on a first analog signal corresponding to the input signal to generate a second analog signal, sample the second analog signal based on the first clock signal, determine N high-order bits corresponding to the second analog signal in a flash-analog-to-digital conversion manner, sample the second analog signal based on the second clock signal, and determine M low-order bits corresponding to the second analog signal in a successive approximation register-analog-to-digital conversion (SAR-ADC) manner. The analog-to-digital conversion circuit includes a plurality of capacitors including N first capacitors and M second capacitors, N first switches coupled with a respective first capacitor of the N first capacitors, and configured to switch between a first reference voltage and a second reference voltage, and M second switches coupled with a respective second capacitor of the M second capacitors, and configured to switch between the first reference voltage and the second reference voltage. The analog-to-digital conversion circuit is further configured to determine the M low-order bits in the SAR-ADC manner based on the M second capacitors and the M second switches after the N first switches are switched based on the N high-order bits. N is a first positive integer greater than or equal to 1, and Mis a second positive integer greater than or equal to 1.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a block diagram illustrating an electronic device, according to an embodiment;

FIG. 2 is a block diagram illustrating an analog-to-digital conversion circuit, according to an embodiment;

FIG. 3 is a circuit diagram illustrating a flash-to-analog-digital converter, according to an embodiment;

FIG. 4 is a diagram illustrating a time interleaving-analog-to-digital conversion circuit, according to an embodiment;

FIG. 5 is a graph of spurious noise according to sampling frequency, according to an embodiment;

FIGS. 6A and 6B are circuit diagrams illustrating an operation of a successive approximation register-analog-to-digital converter (SAR-ADC) included in a time interleaving-analog-to-digital conversion circuit, according to an embodiment;

FIG. 7 is a timing diagram of an analog-to-digital conversion circuit, according to an embodiment;

FIG. 8 is a flowchart illustrating an operating method of an analog-to-digital conversion circuit, according to an embodiment;

FIG. 9 is a block diagram illustrating a communication device including an analog-to-digital conversion circuit, according to an embodiment; and

FIG. 10 is a block diagram illustrating a system-on-chip including an analog-to-digital conversion circuit, according to an embodiment.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, or the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

Hereinafter, various embodiments of the present disclosure are described with reference to the accompanying drawings.

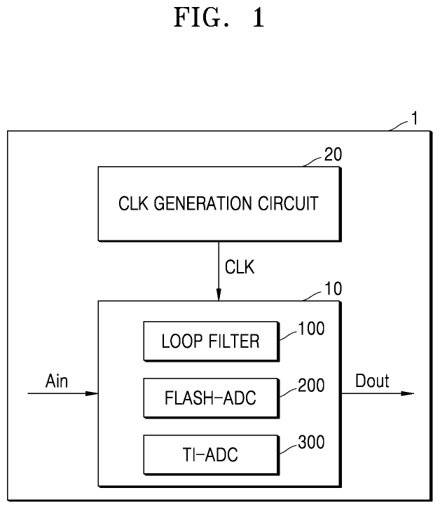

FIG. 1 is a block diagram illustrating an electronic device 1, according to an embodiment.

Referring to FIG. 1, the electronic device 1, according to the present disclosure, may include a clock signal (CLK) generation circuit 20 and an analog-to-digital conversion (ADC) circuit 10. As used herein, an analog-to-digital converter may be referred to as an ADC, and an analog-to-digital conversion circuit 10 may be referred to as an ADC circuit.

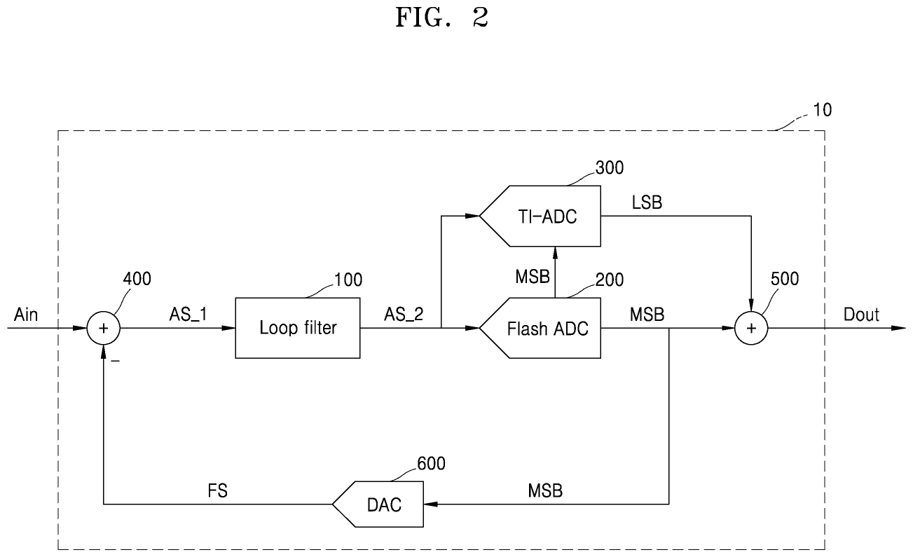

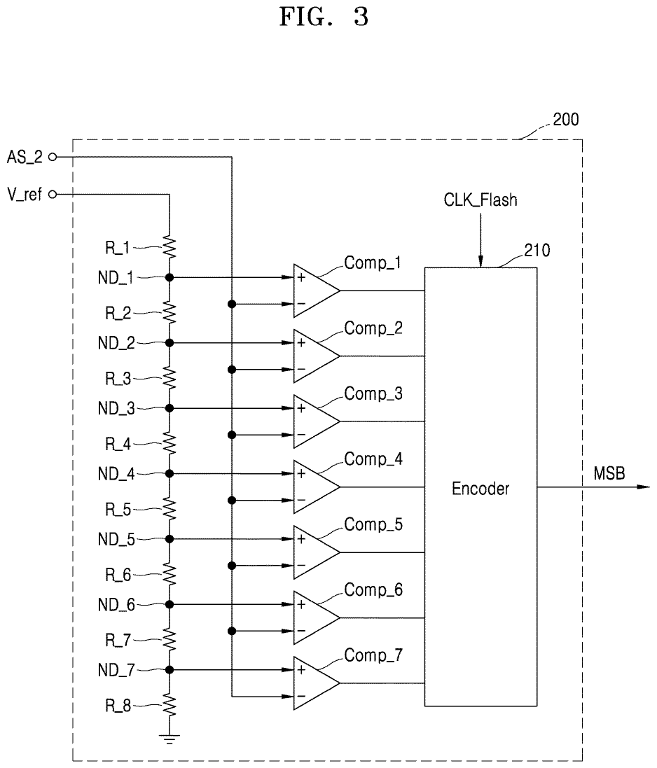

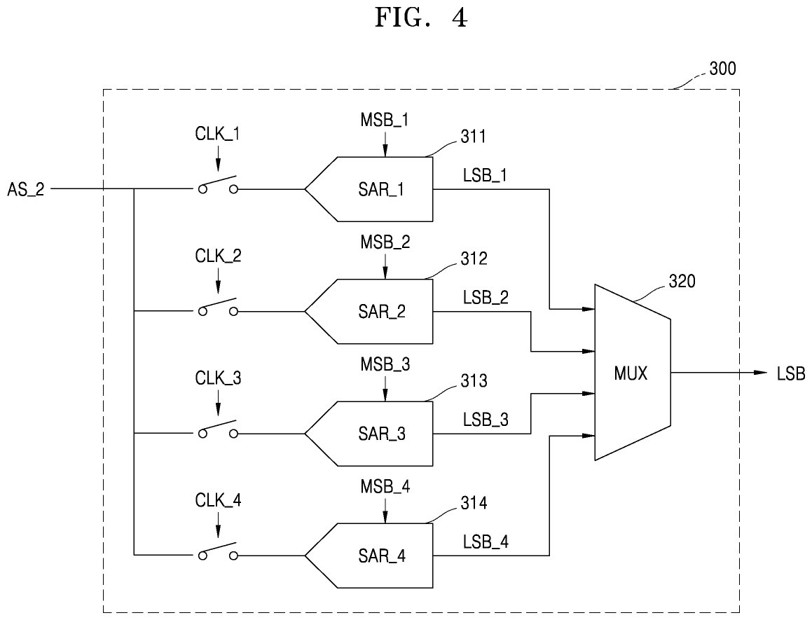

The CLK generation circuit 20 may generate a clock signal CLK. The CLK generation circuit 20 may output the clock signal CLK to the ADC circuit 10. The clock signal CLK, according to the present disclosure, may include a plurality of clock signals described below. For example, the clock signal CLK may include a flash clock signal (e.g., CLK_Flash of FIG. 3) for an analog-to-digital conversion operation of a flash-ADC (e.g., a flash-ADC 200 of FIG. 2) and a plurality of clock signals (e.g., a first clock signal CLK_1, a second clock signal CLK_2, a third clock signal CLK_3, and a fourth clock signal CLK_4 of FIG. 4) for analog-to-digital conversion operations of each of a plurality of successive approximation register (SAR)-ADCs.

The ADC circuit 10, according to the present disclosure, may include a loop filter 100, a flash-ADC 200, and a time-interleaving-ADC 300. As used herein, the flash-to-analog-digital converter 200 may be referred to as a flash-ADC and the time-interleaving ADC 300 may be referred to as a TI-ADC.

The ADC circuit 10 may receive the clock signal CLK from a CLK generation circuit 20. The ADC circuit 10 may receive an input signal Ain. The input signal Ain may be an analog signal. The ADC circuit 10 may convert the input signal Ain based on the clock signal CLK to generate an output signal Dout. The output signal Dout may be a digital signal. That is, the ADC circuit 10, according to the present disclosure, may perform high-speed, high-resolution analog-to-digital conversion on the input signal Ain through the flash-ADC 200 and the TI-ADC 300 based on the clock signal CLK to generate the output signal Dout.

Each of the loop filter 100, flash-ADC 200, and TI-ADC 300, according to the present disclosure, are further described below.

For convenience of description, although the CLK generation circuit 20 is illustrated in FIG. 1 as being configured independently from the ADC circuit 10, the CLK generation circuit 20, according to the present disclosure, may be included in the ADC circuit 10.

FIG. 2 is a block diagram illustrating the ADC circuit 10, according to an embodiment.

Referring to FIG. 2, the ADC circuit 10 may include the loop filter 100, the flash-ADC 200, the TI-ADC 300, a first adder 400, a second adder 500, and a digital-to-analog converter (DAC) 600. As used herein, the digital-to-analog converter 600 may be referred to as a DAC.

The ADC circuit 10, according to the present disclosure, may convert the input signal Ain, which may be an analog signal, to generate the output signal Dout, which may be a digital signal, as described above with reference to FIG. 1.

The first adder 400, according to an embodiment, may receive the input signal Ain from the outside. As used herein, outside may refer to outside the ADC circuit 10 and/or outside the electronic device (e.g., the electronic device 1 in FIG. 1). For example, the input signal Ain may be generated by the electronic device 1 and converted from an analog signal to a digital signal by the ADC circuit 10. Alternatively or additionally, the input signal Ain may be an analog signal received from outside of the electronic device 1 by the electronic device 1 and may be converted from an analog signal to a digital signal by the ADC circuit 10.

The first adder 400 may receive a feedback signal FS from the DAC 600. The first adder 400 may generate a first analog signal AS_1 based on the input signal Ain and the feedback signal FS. For example, the first adder 400 may generate a first analog signal AS_1 based on a difference between the input signal Ain and the feedback signal FS.

The loop filter 100 may receive the first analog signal AS_1 from the first adder 400. The loop filter 100 may filter the first analog signal AS_1. For example, the loop filter 100 may remove and/or attenuate signal components having a certain frequency from among the signal components included in the first analog signal AS_1.

The ADC circuit 10, according to the present disclosure, may be and/or may include a delta-sigma modulator (DSM) including a feedback loop. As used herein, the feedback loop may refer to a loop including the first adder 400, the loop filter 100, the flash-ADC 200, the TI-ADC 300, and the DAC 600. As used herein, the delta-sigma modulator may be referred to as DSM. The ADC circuit 10, according to the present disclosure, may perform noise shaping through an oversampling characteristic of the DSM to calibrate (and/or compensate for) a mismatch that may occur between the plurality of ADCs included in the TI-ADC 300 and thereby alleviate a performance degradation due to the mismatch. As used herein, oversampling may refer to sampling a signal at a frequency higher than the Nyquist frequency. Noise shaping may refer to a filtering operation that may reduce noise in low frequency bands and/or may push noise into high frequency bands. The loop filter 100 may include an integrator having a relatively high gain in a low frequency band, thereby performing noise shaping to reduce quantization noise (e.g., in-band noise, as described below with reference to FIG. 3) within a signal frequency band. The loop filter 100 may act as a low pass filter for a signal frequency band, thereby potentially improving a signal-to-noise ratio (SNR) of the filtered signals.

The oversampling ratio, according to the present disclosure, may be greater than the number of the plurality of ADCs included in the TI-ADC 300. As used herein, the oversampling ratio may be referred to as OSR, and the OSR may refer to a ratio of a sampling frequency of the DSM to a signal band of the input signal Ain. The OSR, according to the present disclosure, may be greater than or equal to the number of ADCs included in the TI-ADC 300. The ADC circuit 10, according to the present disclosure, may perform oversampling based on the OSRs, and may perform noise shaping on the input signal Ain through oversampling. For example, the ADC circuit 10 may calibrate a mismatch that may occur between the plurality of ADCs included in the TI-ADC 300 without a separate calibration circuit through noise shaping. Accordingly, the ADC circuit 10 may not include a calibration circuit for a calibrating mismatch, and thus, the ADC circuit 10 may perform high-resolution analog-to-digital conversion without increasing the area and power consumption of the ADC circuit 10, when compared to related ADC circuits.

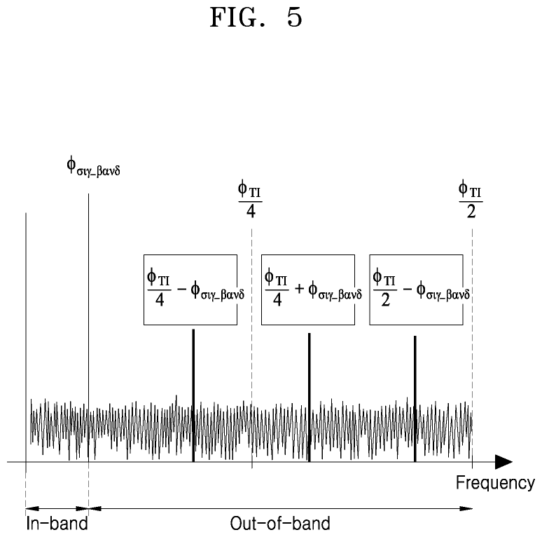

Each of the flash-ADC 200 and the TI-ADC 300, according to the present disclosure, may receive a second analog signal AS_2 from the loop filter 100. The flash-ADC 200 may perform analog-to-digital conversion on the second analog signal AS_2 to generate a most significant bit (MSB) corresponding to the second analog signal AS_2. The MSB may include at least one bit and may refer to at least one high-order bit included in the output signal Dout. The TI-ADC 300 may receive the MSB from the flash-ADC 200. The TI-ADC 300 may perform analog-to-digital conversion on the second analog signal AS_2 based on the MSB to generate a least significant bit (LSB) corresponding to the second analog signal AS_2. The LSB may include at least one bit and may refer to at least one low-order bit excluding the MSB included in the output signal Dout. The flash-ADC 200 is further described below with reference to FIG. 4, and the TI-ADC 300 is further described below with reference to FIG. 5.

The ADC circuit 10, according to the present disclosure, may generate the MSB and the LSB included in the output signal Dout, based on each of the flash-ADC 200 and the TI-ADC 300 as described above, thereby potentially improving an analog-to-digital conversion speed of the ADC circuit 10, when compared to related ADC circuits.

The second adder 500 may receive the MSB from the flash-ADC 200 and the LSB from the TI-ADC 300. The second adder 500 may generate the output signal Dout, based on the MSB and LSB. For example, if the MSB is ‘101’ and the LSB is ‘010’, the output signal Dout may be ‘101010’. The number of bits included in each of the MSB and LSB, according to the present disclosure, is not limited to the aforementioned examples and may vary depending on the number of resistors included in the flash-ADC 200, according to design constraints.

The DAC 600 may receive the MSB from the flash-ADC 200. The DAC 600 may convert the MSB from digital to analog to generate the feedback signal FS. Although the DAC 600 is illustrated in FIG. 2 as receiving the MSB from the flash-ADC 200, embodiments of the present disclosure are not limited thereto. For example, the DAC 600 may receive the output signal Dout and convert the output signal Dout from digital to analog to generate the feedback signal FS. By feeding back the MSB and/or output signal Dout corresponding to the analog-to-digital conversion result for the input signal Ain by the DAC 600, the loop filter 100 may perform the aforementioned noise shaping, and the error of the analog-to-digital conversion may be reduced, when compared to related ADC circuits.

FIG. 3 is a circuit diagram illustrating the flash-ADC 200, according to an embodiment.

Referring to FIG. 3, the flash-ADC 200 may include a plurality of resistors (e.g., a first resistor R_1, a second resistor R_2, a third resistor R_3, a fourth resistor R_4, a fifth resistor R_5, a sixth resistor R_6, a seventh resistor R_7, and an eighth resistor R_8), a plurality of comparators (e.g., a first comparator Comp_1, a second comparator Comp_2, a third comparator Comp_3, a fourth comparator Comp_4, a fifth comparator Comp_5, a sixth comparator Comp_6, and a seventh comparator Comp_7), and an encoder 210.

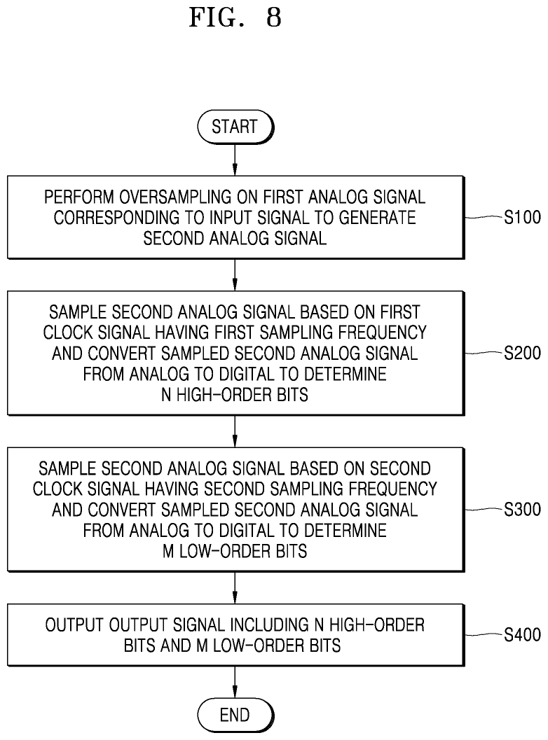

As described above, the flash-ADC 200 may receive the second analog signal AS_2 and generate an MSB corresponding to the second analog signal AS_2. The encoder 210 may output the MSB by performing an operation described below based on the flash clock signal CLK_Flash. The operation of the flash-ADC 200, according to the flash clock signal CLK_Flash, is further described below with reference to FIG. 8.

Referring to FIG. 3, the flash-ADC 200 may receive the second analog signal AS_2 and a reference voltage V_ref. Each of the first to seventh comparators Comp_1 to Comp_7 may compare two (2) applied voltages and output comparison results to the encoder 210. A combination of comparison results output from each of the first to seventh comparators Comp_1 to Comp_7 may be referred to as a thermometer code. The encoder 210 may receive the thermometer code according to the comparison results from the first to seventh comparators Comp_1 to Comp_7 and output an MSB corresponding to the thermometer code.

For example, assuming that the resistance values of the first to eighth resistors R_1 to R_8 may be the same, a voltage of the second analog signal AS_2 may be 5.5 volts (V), and the reference voltage V_ref may be 8 V, 7 V may be applied to a first node ND_1 between the first resistor R_1 and the second resistor R_2, 6 V may be applied to a second node ND_2 between the second resistor R_2 and the third resistor R_3, 5 V may be applied to a third node ND_3 between the third resistor R_3 and the fourth resistor R_4, 4 V may be applied to a fourth node ND_4 between the fourth resistor R_4 and the fifth resistor R_5, 3 V may be applied to a fifth node ND_5 between the fifth resistor R_5 and the sixth resistor R_6, 2 V may be applied to a sixth node ND_6 between the sixth resistor R_6 and the seventh resistor R_7, and 1 V may be applied to a seventh node ND_7 between the seventh resistor R_7 and the eighth resistor R_8.

Accordingly, the first comparator Comp may compare the second analog signal AS_2 with the voltage (e.g., 7 V) applied to the first node ND_1, and because the voltage of the first node ND_1 is higher than the voltage of the second analog signal AS_2, the first comparator Comp may output a logic low signal (e.g., ‘0’) as a comparison result to the encoder 210. Similarly, the second to seventh comparators Comp_2 to Comp_7 may output ‘0’, ‘1’, ‘1’, ‘1’, ‘1’, and ‘1’ to the encoder 210, respectively. That is, the thermometer code may be ‘0011111’, and the encoder 210 may output ‘101’, which is the MSB corresponding to ‘0011111’. As another example, if the thermometer code is ‘1111111’, the corresponding MSB may be ‘111’, and if the thermometer code is ‘0111111’, the corresponding MSB may be ‘110’.

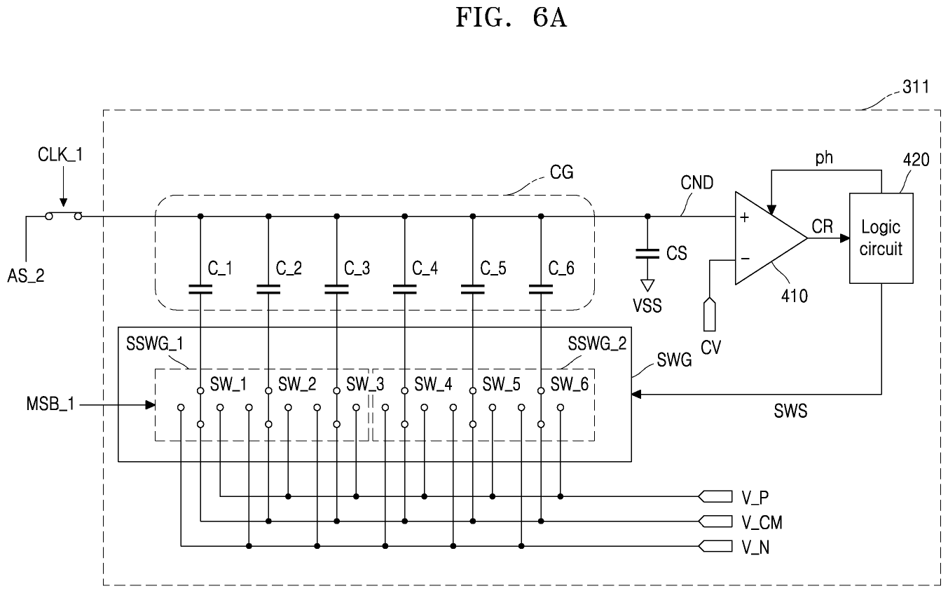

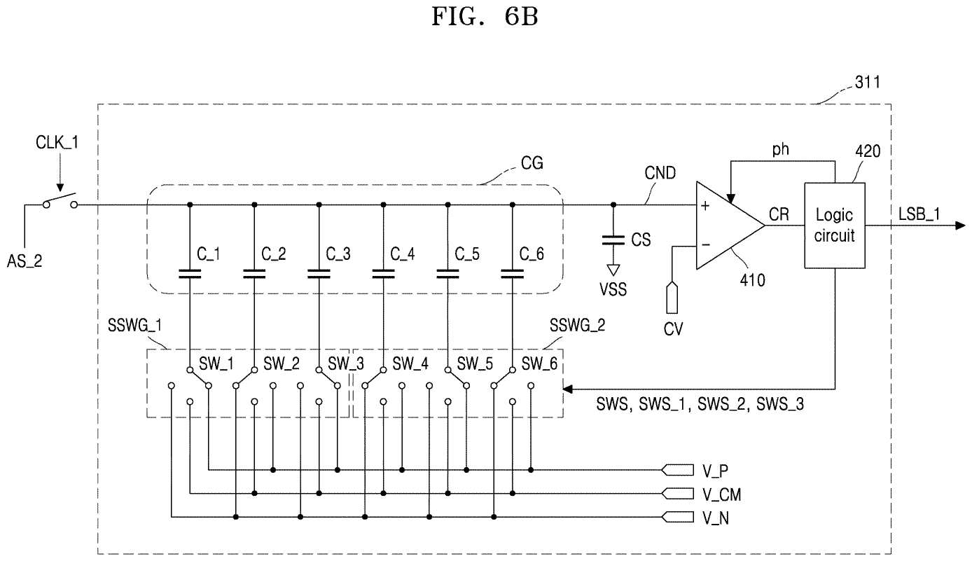

As described above with reference to FIG. 3, the flash-ADC 200 may rapidly perform an analog-to-digital conversion operation, when compared to related ADC circuits, on the second analog signal AS_2 by comparing the second analog signal AS_2 and the reference voltage V_ref in parallel through the first to seventh comparators Comp_1 to Comp_7. The flash-ADC 200, according to the present disclosure, may perform analog-to-digital conversion on the second analog signal AS_2 to generate an MSB and output the MSB to the TI-ADC 300. As described below, the TI-ADC 300 may include the plurality of ADCs, and each ADC of the plurality of ADCs may be and/or may include an SAR-ADC. As described below, the SAR-ADC may sequentially compare voltages applied to the comparator 410 to generate each bit from the high-order bit to the low-order bit, and as such, the speed of analog-to-digital conversion may be relatively slow compared to the flash-ADC 200. Accordingly, as described below, the TI-ADC 300, according to the present disclosure, may receive the MSB for the second analog signal AS_2 from the flash-ADC 200 and generate only the LSB corresponding to the second analog signal AS_2 based on the MSB, thereby potentially improving the analog-to-digital conversion speed for the second analog signal AS_2, when compared to related ADC circuits. In this regard, descriptions are given with reference to FIGS. 6A and 6B below.

The number of resistors, the number of comparators, and the number of bits included in the MSB illustrated in FIG. 3 are examples for describing the flash-ADC 200 and the flash-ADC 200. However, embodiments of the present disclosure are not limited thereto. For example, if the flash-ADC 200 outputs an MSB including N bits, the number of comparators included in the flash-ADC 200 may be 2^{N}−1. That is, the number of comparators included in the flash-ADC 200 may be determined according to the number of bits included in the MSB output from the flash-ADC 200.

FIG. 4 is a diagram illustrating a time interleaving-ADC circuit, according to an embodiment.

Referring to FIG. 4, the TI-ADC 300 may include a plurality of ADCs (e.g., a first ADC 311, a second ADC 312, a third ADC 313, and a fourth ADC 314) and a multiplexer 320. Hereinafter, FIG. 4 may be described on the assumption that each of the first to fourth ADCs 311 to 314 is a SAR-ADC. However, embodiments of the present disclosure are not limited thereto, and each of the first to fourth ADCs 311 to 314, according to the present disclosure, may be and/or may include other types of ADCs. In addition, although the TI-ADC 300 is illustrated in FIG. 4 as including four (4) ADCs, embodiments of the present disclosure are not limited thereto, and the number of ADCs in the plurality of ADCs included in the TI-ADC 300 may be less than four (4) (e.g., three (3) or less) or greater than four (4) (e.g., five (5) or more).

Each of the first to fourth ADCs 311 to 314, according to the present disclosure, may operate in a time-interleaving manner. Each of the first to fourth ADCs 311 to 314 may alternately sample the second analog signal AS_2 based on the first to fourth clock signals CLK_1 to CLK_4 having different phases. Each of the first to fourth ADCs 311 to 314 may perform analog-to-digital conversion on the sampled second analog signal AS_2 and a plurality of LSBs (e.g., a first LSB LSB_1, a second LSB LSB_2, a third LSB LSB_3, and a fourth LSB LSB_4) as digital signals. The TI-ADC 300 may perform analog-to-digital conversion like an ADC performing a single high-speed operation by controlling each of the first to fourth ADCs 311 to 314 in a time-interleaving manner based on the first to fourth clock signals CLK_1 to CLK_4.

That is, each of the first to fourth ADCs 311 to 314 may be sequentially selected to receive the second analog signal AS_2, sample the second analog signal AS_2 in response to an edge (e.g., a rising edge or a falling edge) of a clock signal corresponding to each of the first to fourth ADCs (or at an edge of the clock signal), and perform analog-to-digital conversion on the sampled signal to output an LSB (e.g., the first to fourth LSBs LSB_1 to LSB_4). For example, the first ADC 311 may sample the second analog signal AS_2 in response to an edge of the first clock signal CLK_1 and may perform analog-to-digital conversion on the sampled second analog signal AS_2 to output the first LSB LSB_1. Similarly, each of the second to fourth ADCs 312 to 314 may sample the second analog signal AS_2 in response to an edge of each of the second to fourth clock signals CLK_2 to CLK_4 and may perform analog-to-digital conversion on the sampled second analog signal AS_2 to output the second to fourth LSBs LSB_2 to LSB_4. For example, the second clock signal CLK_2 may be a signal delayed more than the first clock signal CLK_1, the third clock signal CLK_3 may be a signal delayed more than the second clock signal CLK_2, and the fourth clock signal CLK_4 may be a signal delayed more than the third clock signal CLK_3. Accordingly, each of the first to fourth ADCs 311 to 314 may sequentially sample the second analog signal AS_2 and output an LSB corresponding to the sequentially sampled second analog signal AS_2.

Each of the first to fourth ADCs 311 to 314, according to the present disclosure, may receive an MSB from the flash-ADC 200 and generate an LSB based on the MSB. As described above, each of the first to fourth ADCs 311 to 314 may be a SAR-ADC, and the SAR-ADC may sequentially compare the high-order bits to the low-order bits. Accordingly, each of the first to fourth ADCs 311 to 314, according to the present disclosure, may receive the MSB from the flash-ADC 200 and generate only the LSB excluding the MSB among the plurality of bits corresponding to the second analog signal AS_2, thereby potentially improving the analog-to-digital conversion speed, when compared to a related ADC circuit.

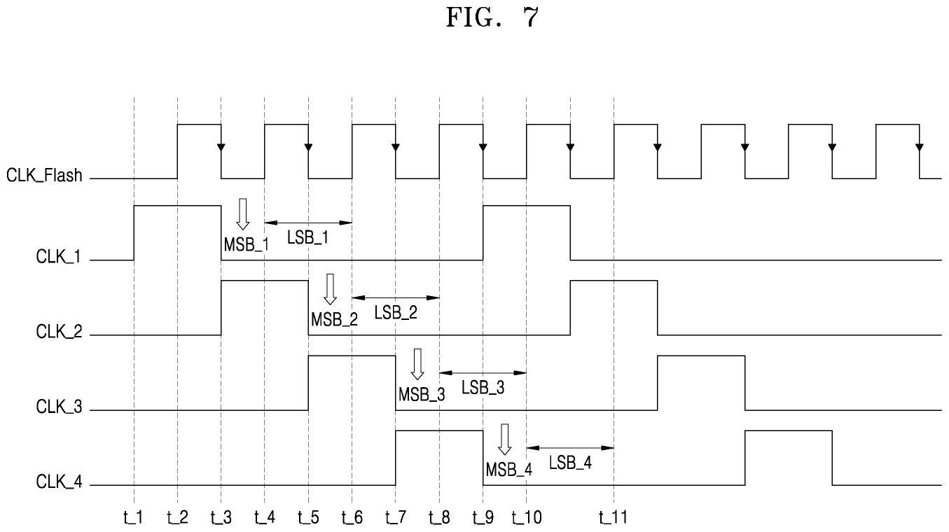

For example, the first ADC 311 may receive a first MSB MSB_1 from the flash-ADC 200 and generate a first LSB LSB_1 based on the first MSB MSB_1. Similarly, the second to fourth ADCs 312 to 314 may sequentially receive the second to fourth MSBs MSB_2 to MSB_4 respectively from the flash-ADC 200 and generate second to fourth LSBs LSB_2 to LSB_4 based on the second to fourth MSBs MSB_2 to MSB_4. The analog-to-digital conversion operation of each of the first to fourth ADCs 311 to 314, according to the present disclosure, is further described below with reference to FIGS. 6A, 6B, and 7.

The multiplexer 320 may sequentially receive the first to fourth LSBs LSB_1 to LSB_4 from each of the first to fourth ADCs 311 to 314 and may sequentially output the first to fourth LSBs LSB_1 to LSB_4. Although FIG. 4 illustrates the multiplexer 320 as outputting the LSB, such an example is only for convenience of description and embodiments of the present disclosure are not limited thereto. For example, the multiplexer 320 may perform the operation of the second adder 500 and output the output signal Dout based on the MSB and the LSB. That is, the multiplexer 320 may output a first output signal by combining the first MSB MSB_1 and the first LSB LSB_1 and may sequentially output a second output signal generated based on the second MSB MSB_2 and the second LSB LSB_2, a third output signal generated based on the third MSB MSB_3 and the third LSB LSB_3, and a fourth output signal generated based on the fourth MSB MSB_4 and the fourth LSB LSB_4.

FIG. 5 is a graph of spurious noise according to a sampling frequency, according to an embodiment.

The horizontal axis of FIG. 5 may represent a frequency value, and the vertical axis may represent an intensity of signal and noise.

As described above with reference to FIG. 2, the loop filter 100 may perform noise shaping on the first analog signal AS_1 to generate the second analog signal AS_2. That is, the loop filter 100 may receive the MSB fed back through the feedback signal FS from the TI-ADC and may perform noise shaping on the first analog signal AS_1, based on the MSB and the aforementioned OSR. Also, as described above with reference to FIG. 4, the TI-ADC 300 may sample the second analog signal AS_2 at the first sampling frequency f_{TI}. That is, the first sampling frequency f_{TI} may be a frequency of the first to fourth clock signals CLK_1 to CLK_4 described above with reference to FIG. 4. As described above, the OSR may be a ratio of a sampling frequency of the DMS to a signal band f_{sig_band} of the input signal Ain. As used herein, the sampling frequency of the DSM may refer to a sampling frequency f_{TI} of the TI-ADC 300 that performs analog-to-digital conversion. Consequently, the relationship between the signal band f_{sig_band} of the input signal Ain and the sampling frequency f_{TI} of the TI-ADC 300 may be represented as an equation similar to Equation 1.

$${f}_{sig \_ band} = \frac{{f}_{TI}}{2 \cdot OSR} \qquad [ Equation 1 ]$$

A k-th spurious component that may occur in an output signal based on a mismatch between the plurality of ADCs included in the TI-ADC 300 in FIG. 2, according to the present disclosure, may be expressed mathematically as an equation similar to Equation 2.

$${f}_{spur , k} = \pm {f}_{sig \_ band} + \frac{k}{B} {f}_{TI} \qquad [ Equation 2 ]$$

Referring to Equation 2, B may represent the number of ADCs included in the TI-ADC 300 in FIG. 2, k may represent a natural number less than or equal to B, and f_{spur,k} may represent the k-th spurious component. Spurious components may refer to unintended noise components, which may be and/or may include frequency components corresponding to unwanted peaks in a frequency spectrum. For example, the graph shown in FIG. 5 is a spurious noise graph when the number of ADCs B included in the TI-ADC 300 is four (4) and the OSR is one (1) (e.g., a Nyquist sampling method). As described above, the spurious component may be due to a mismatch between the plurality of ADCs of the TI-ADC 300. Therefore, it may be necessary to calibrate the mismatch to eliminate and/or alleviate the influence of spurious components on the output signal.

The ADC circuit 10 may perform noise shaping by oversampling the input signal to push a noise component of the signal out of in-band and position the noise component of the signal out-of-band. When the spurious component corresponding to the lowest frequency is located out-of-band, the loop filter 100 may perform low-pass filtering, thereby filtering the spurious component. Therefore, the SNR of the signal band may be improved, thereby potentially improving the resolution of the output signal Dout, when compared to related ADC circuits.

Referring to Equation 2, the spurious component corresponding to the lowest frequency may be when k is equal to one (1) (e.g., k=1). Accordingly, when Equation 3 below is satisfied, the spurious component corresponding to the lowest frequency may be located out-of-band, and the influence of the mismatch between the plurality of ADCs of the TI-ADC 300 may be alleviated and/or eliminated.

OSR≥B [Equation 3]

Accordingly, the ADC circuit 10, according to the present disclosure, may oversample the input signal Ain based on the OSR being greater than or equal to the number of the plurality of ADCs included in the TI-ADC 300, thereby alleviating and/or eliminating the influence of the mismatch between the plurality of ADCs included in the TI-ADC 300. Accordingly, the ADC circuit 10, according to the present disclosure, may alleviate and/or eliminate the influence of the mismatch between the plurality of ADCs included in a TI-ADC 300 without a separate calibration circuit that may perform calibration on the mismatch.

FIGS. 6A and 6B are circuit diagrams illustrating the operation of an SAR-ADC included in a time interleaving-ADC circuit, according to an embodiment.

The first ADC 311 illustrated in FIGS. 6A and 6B may include and/or may be similar in many respects to the first ADC 311 described above with reference to FIG. 4, and may include additional features not mentioned above. Consequently, repeated descriptions of the first ADC 311 described above with reference to FIG. 4 may be omitted for the sake of brevity. In addition, the operation and circuit diagram of each of the second to fourth ADCs 312 to 314 described above with reference to FIG. 4 may be understood with reference to the first ADC 311 described with reference to FIGS. 6A and 6B.

Referring to FIG. 6A, the first ADC 311, according to the present disclosure, may be and/or may include a SAR-ADC. The first ADC 311 may include a comparator 410, a logic circuit 420, a capacitor group CG, a common capacitor CS, and a switch array SWG. The capacitor group CG may be referred to as a capacitive digital-to-analog converter (CDAC), and as described below, the first ADC 311 may sample the second analog signal AS_2 based on the first clock signal CLK_1 and may sequentially determine a bit corresponding to the second analog signal AS_2, according to a charge conservation law.

The capacitor group CG, according to an embodiment, may include a first capacitor C_1, a second capacitor C_2, a third capacitor C_3, a fourth capacitor C_4, a fifth capacitor C_5, and a sixth capacitor C_6. However, the number of capacitors included in the capacitor group CG is not limited thereto, and the number of capacitors included in the capacitor group CG may vary depending on the number of bits included in each of the MSB received and the LSB output by the first ADC 311.

Referring to FIG. 6A, each of the first to sixth capacitors C_1 to C_6 may be connected to a comparison reference node CND. That is, the first to sixth capacitors C_1 to C_6 may share the comparison reference node CND. Each of the first to sixth capacitors C_1 to C_6 may have different capacitances. For example, among the first to sixth capacitors C_1 to C_6, the capacitance may decrease from the first capacitor C_1 to the sixth capacitor C_6. As another example, the capacitance size may increase by two (2) times (e.g., 2×) from the sixth capacitor C_6 to the first capacitor C_1. That is, when the capacitance of the sixth capacitor C_6 is C, the capacitance of the fifth capacitor C_5 may be 2×C, the capacitance of the fourth capacitor C_4 may be 4×C, the capacitance of the third capacitor C_3 may be 8×C, the capacitance of the second capacitor C_×2 may be 16×C, and the capacitance of the first capacitor C_1 may be 32×C.

The common capacitor CS may be connected between the comparison reference node CND and a ground voltage VSS. Although FIGS. 6A and 6B illustrate the common capacitor CS as being connected to the ground voltage VSS, embodiments of the present disclosure are not limited thereto. For example, the common capacitor CS may be connected between the comparison reference node CND and a first reference voltage V_CM.

Referring to FIG. 6A, the switch array SWG may include a first switch SW_1, a second switch SW_2, a third switch SW_3, a fourth switch SW_4, a fifth switch SW_5, and a sixth switch SW_6. The first to sixth switches SW_1 to SW_6 included in the switch array SWG may respectively correspond to the first to sixth capacitors C_1 to C_6 and may be connected between the first to sixth capacitors C_1 to C_6 and a second reference voltage V_P, the first reference voltage V_CM, and a third reference voltage V_N. Each of the first to sixth switches SW_1 to SW_6 may be connected to any one of the first reference voltage V_CM, the second reference voltage V_P, and the third reference voltage V_N in response to a switch control signal SWS provided from the logic circuit 420. By switching each of the first to sixth switches SW_1 to SW_6, a voltage level of the comparison reference node CND may be changed to preserve the amount of charge stored in each of the first to sixth capacitors C_1 to C_6 and the common capacitor CS.

Referring to FIG. 6A, the logic circuit 420 may generate a comparator control signal ph and the switch control signal SWS. The logic circuit 420 may provide the comparator control signal ph to the comparator 410. The comparator 410 may compare the levels of voltages received by an inverting terminal and a non-inverting terminal based on the comparator control signal ph.

Referring to FIG. 6A, the comparator 410 may compare a voltage level of the comparison reference node CND applied to the non-inverting terminal and a voltage level of a comparison voltage CV received by the inverting terminal based on the comparator control signal ph. For example, the comparison voltage CV may be substantially similar and/or equal to the first reference voltage V_CM, however, embodiments of the present disclosure are not limited thereto.

The comparator 410 may compare the levels of voltages applied to the inverting terminal and the non-inverting terminal based on the comparator control signal ph to generate a comparison result CR. For example, when the voltage level of the comparison reference node CND applied to the non-inverting terminal is higher than the voltage level of the comparison voltage CV applied to the inverting terminal, the comparator 410 may provide the corresponding comparison result CR to the logic circuit 420. In such an example, the logic circuit 420 may generate comparison data including a logic high level (e.g., “1”) based on the comparison result CR. When the voltage level of the comparison reference node CND applied to the non-inverting terminal is lower than the voltage level of the comparison voltage CV applied to the inverting terminal, the comparator 410 may provide the corresponding comparison result CR to the logic circuit 420. In such an example, the logic circuit 420 may generate comparison data including a logic low level (e.g., “0”) based on the comparison result CR.

The logic circuit 420 may generate the switch control signal SWS based on the comparison data (e.g., “1” or “0”). Each of the first to sixth switches SW_1 to SW_6 may be connected to any one of the second reference voltage V_P and the third reference voltage V_N based on the switch control signal SWS. For example, if the comparison data is a logic high (e.g., “1”), the logic circuit 420 may provide the switch control signal SWS to a switch corresponding to the comparison data to be connected to the second reference voltage V_P. If the comparison data is a logic low (e.g., “0”), the logic circuit 420 may provide the switch control signal SWS to a switch corresponding to the comparison data to be connected to the third reference voltage V_N. That is, the first ADC 311 may determine each bit from the most significant bit (MSB) to the least significant bit (LSB) and may determine a next bit based on a previously determined bit. Consequently, in order to determine N bits, the comparator 410 may need to perform N comparisons, which may result in a relatively long analog-to-digital conversion time.

The switch array SWG, according to the present disclosure, may include a first sub-switch array SSWG_1 and a second sub-switch array SSWG_2. The first sub-switch array SSWG_1 may include first to third switches SW_1 to SW_3. The second sub-switch array SSWG_2 may include fourth to sixth switches SW_4 to SW_6. However, embodiments of the present disclosure are not limited thereto, and the first to sixth switches SW_1 to SW_6 may be grouped into a different number of groups and/or different groups without departing from the scope of the present disclosure.

Referring to FIG. 6A, the first ADC 311, according to an embodiment, may sample the second analog signal AS_2 based on the first clock signal CLK_1. As the second analog signal AS_2 is sampled, a voltage level of the second analog signal AS_2 is applied to the comparison reference node CND. Each of the first to sixth switches SW_1 to SW_6 may be connected to the first reference voltage V_CM.

After sampling of the second analog signal AS_2 is completed, the first ADC 311 may receive the first MSB MSB_1 from the flash-ADC 200. The first to third switches SW_1 to SW_3 included in the first sub-switch array SSWG_1 may be switched based on the first MSB MSB_1. For example, the first MSB MSB_1 may include three (3) bits, and the three (3) bits may be ‘101’. In response to the most significant bit included in the first MSB MSB_1 being a logic high level (e.g., “1”), the first switch SW_1 may be switched to be connected to the second reference voltage V_P. Similarly, the second switch SW_2 may be switched to be connected to the third reference voltage V_N, and the third switch SW_3 may be switched to be connected to the second reference voltage V_P. As the first to third switches SW_1 to SW_3 are switched based on the first MSB MSB_1, the voltage level of the comparison reference node CND may be changed by the charge conservation law.

In reference to FIG. 6B, the first to third switches SW_1 to SW_3 may be switched based on the first MSB MSB_1 (e.g., ‘101’) as described above with reference to FIG. 6A. The first ADC 311, according to the present disclosure, may generate the first LSB LSB_1 by comparing the voltage level applied to the comparison reference node CND with the comparison voltage CV. Referring to FIG. 6B, the comparator 410 may compare the changed voltage level of the comparison reference node CND with the comparison voltage CV to output a comparison result CR, and the logic circuit 420 may output a first switch control signal SWS_1 for controlling the fourth switch SW_4 based on the comparison result CR. For example, based on the first MSB MSB_1, the first to third switches SW_1 to SW_3 may be switched so that the changed voltage level of the comparison reference node CND may be lower than that of the comparison voltage CV. Accordingly, the first comparison data may be a logic low level (e.g., ‘0’), and the logic circuit 420 may output the first switch control signal SWS_1 to the fourth switch SW_4 so that the fourth switch SW_4 is connected to the third reference voltage V_N.

As the fourth switch SW_4 is connected to the third reference voltage V_N, the voltage level applied to the comparison reference node CND may be changed. The comparator 410 may compare the changed voltage level of the comparison reference node CND with the comparison voltage CV to output a comparison result CR, and the logic circuit 420 may output a second switch control signal SWS_2 for controlling a fifth switch SW_5 based on the comparison result CR. For example, referring to FIG. 6B, in response to the first comparison data being a logic low level (e.g., ‘0’), the fourth switch SW_4 may be switched so that the changed voltage level of the comparison reference node CND may be higher than the comparison voltage CV. Accordingly, the second comparison data may be a logic high level (e.g., ‘1’), and the logic circuit 420 may output the second switch control signal SWS_2 to the fifth switch SW_5 so that the fifth switch SW_5 is connected to the second reference voltage V_P.

As the fifth switch SW 5 is connected to the second reference voltage V_P, the voltage level applied to the comparison reference node CND may be changed. The comparator 410 may compare the changed voltage level of the comparison reference node CND with the comparison voltage CV to output a comparison result CR, and the logic circuit 420 may output a third switch control signal SWS_3 for controlling a sixth switch SW_6 based on the comparison result CR. For example, referring to FIG. 6B, in response to the second comparison data being a logic high level (e.g., ‘1’), the fifth switch SW_5 may be switched so that the changed voltage level of the comparison reference node CND may be lower than the comparison voltage CV. Accordingly, the third comparison data may be a logic low level (e.g., ‘0’), and the logic circuit 420 may output the third switch control signal SWS_3 to the sixth switch SW_6 so that the sixth switch SW_6 is connected to the third reference voltage V_N.

Referring to the aforementioned example, the first ADC 311, according to the present disclosure, may receive the first MSB MSB_1 from the flash-ADC 200 and generate comparison data based on the first MSB MSB_1. Referring to FIG. 6B, the first comparison data to the third comparison data may be ‘010’ in order, for example. The first to third comparison data may correspond to the LSB of the second analog signal AS_2. Because the analog-to-digital conversion by the first ADC 311 is performed sequentially from the high-order bit, the first ADC 311, according to the present disclosure, may determine the first LSB LSB_1 based on the first MSB MSB_1, thereby shortening the time needed for the analog-to-digital conversion, when compared to related ADC circuits.

The circuit diagram and operation of the first ADC 311, according to the present disclosure, is not limited to the examples described above with reference to FIGS. 6A and 6B. For example, the first ADC 311, according to an embodiment, may further include a plurality of capacitors and/or a plurality of switches symmetrical to the first to sixth capacitors C_1 to C_6 and the first to sixth switches SW_1 to SW_6 with respect to the comparison reference node CND for stability of the analog-to-digital conversion operation. As another example, as described above, the number of switches included in the first ADC 311, according to the present disclosure, the total number of capacitors, and the number of capacitors included in the sub-capacitor group may vary depending on the number of bits included in each of the MSB and the LSB. As another example, the first ADC 311 may determine the first LSB LSB_1 based on two (2) reference voltages.

FIG. 7 is a timing diagram of an ADC circuit, according to an embodiment. Referring to FIG. 7, a timing diagram of an operation of the ADC circuit as described above with reference to FIGS. 1 to 5, 6A, and 6B is illustrated. Consequently, repeated descriptions of the operation of the ADC circuit described above with reference to FIGS. 1 to 5, 6A, and 6B may be omitted for the sake of brevity.

Referring to FIG. 7, the timing diagrams of the flash clock signal CLK_Flash for sampling the second analog signal AS_2 in the flash-ADC 200 and the first to fourth clock signals CLK_1 to CLK_4 for sampling the second analog signal AS_2 in the first to fourth ADCs 311 to 314 included in the TI-ADC 300 are respectively illustrated.

As described above, the analog signal may be sampled in response to an edge (e.g., a rising edge or a falling edge) of the clock signal (or at an edge of the clock signal).

Referring to FIG. 7, the loop filter 100 may perform noise shaping on the first analog signal AS_1 from a first time-point t_1 to a second time-point t_2 and output the second analog signal AS_2 at the second time-point t_2. The second analog signal AS_2 may be output to the flash-ADC 200 and the TI-ADC 300.

Similarly to the above, the flash-ADC 200 may receive the flash clock signal CLK_Flash and sample the second analog signal AS_2 from the second time-point t_2 based on the flash clock signal CLK_Flash. The flash-ADC 200 may output the first MSB MSB_1 to the TI-ADC 300 at a third time-point t_3. The first ADC 311 may receive the first clock signal CLK_1 and may sample the second analog signal AS_2 from the first time-point t_1 to the third time-point t_3 based on the first clock signal CLK_1. The first ADC 311 may receive the first MSB MSB_1 from the third time-point t_3 and may switch at least one switch (e.g., first to third switches SW_1 to SW_3) corresponding to at least one bit included in the first MSB MSB_1 based on the first MSB MSB_1 from the third time-point t_3 to a fourth time-point t_4. The first ADC 311 may determine the first LSB LSB_1 between the fourth time-point t_4 and a sixth time-point t_6. According to the present disclosure, the ADC circuit 10 may generate a first output signal based on the first LSB LSB_1 and the first MSB MSB_1 as the first LSB LSB_1 is determined.

As described above, each of the first to fourth ADCs 311 to 314 included in the TI-ADC 300 may alternately sample the second analog signal AS_2 based on the first to fourth clock signals CLK_1 to CLK_4 having different phases. That is, each of the first to fourth ADCs 311 to 314 may operate in a time-interleaving manner. Accordingly, as illustrated in FIG. 7, each of the first to fourth ADCs 311 to 314 may alternately perform similar operations.

The operation of the first ADC 311 has been described above. Referring to FIG. 7, for each operation of the second to fourth ADCs 312 to 314, the loop filter 100 may perform noise shaping on the first analog signal AS_1 from the third time-point t_3 to the fourth time-point t_4 and output the second analog signal AS_2 at the fourth time-point t_4. The second analog signal AS_2 may be output to the flash-ADC 200 and the TI-ADC 300.

The flash-ADC 200 may sample the second analog signal AS_2 from the fourth time-point t_4 based on the flash clock signal CLK_Flash and output the second MSB MSB_2 for the second analog signal AS_2 sampled from the fourth time-point t_4 to the TI-ADC 300 at a fifth time-point t_5. The second ADC 312 may receive the second clock signal CLK_2 and may sample the second analog signal AS_2 from third time-point t_3 to the fifth time-point t_5 based on the second clock signal CLK_2. The second ADC 312 may receive the second MSB MSB_2 from the fifth time-point t_5, and may switch at least one switch corresponding to at least one bit included in the second MSB MSB_2 based on the second MSB MSB_2 from the fifth time-point t_5 to the sixth time-point t_6. The second ADC 312 may determine the second LSB LSB_2 between the sixth time-point t_6 and an eighth time-point t_8. According to the present disclosure, the ADC circuit 10 may generate a second output signal based on the second LSB LSB_2 and the second MSB MSB_2 as the second LSB LSB_2 is determined

Regarding the operations of the third ADC 313 and the fourth ADC 314, the operations of the third ADC 313 and the fourth ADC 314 at a seventh time-point t_7, an eighth time-point t_8, a ninth time-point t_9, a tenth time-point t_10, and an eleventh time-point t_11 may be understood through the operations described above. Therefore, repeated descriptions thereof may be omitted for the sake of brevity.

The output of the flash-ADC 200 may be initialized at the rising edge of the flash clock signal CLK_Flash. The previous MSB output may be maintained until the falling edge of the flash clock signal CLK_Flash. For example, the previous MSB output may be held by an S-R latch. However, embodiments of the present disclosure are not limited thereto, and the previous MSB output may be held by various other means.

As described above, the OSR, according to the present disclosure, may be greater than or equal to the number of ADCs included in the TI-ADC 300. For example, as shown in FIG. 7, the number of the plurality of ADCs included in the TI-ADC 300 may be four (4), and the sampling frequency of the TI-ADC 300 may be eight (8) times or more of the signal band of the input signal, according to Equation 1. Accordingly, noise components due to a mismatch of the plurality of ADCs included in the TI-ADC 300 may be positioned out-of-band, and by filtering out the noise located out-of-band, the performance of the ADC circuit 10 may be improved, when compared to related ADC circuits. Accordingly, the ADC circuit 10, according to the present disclosure, may not include a separate calibration circuit for calibrating a mismatch. In addition, the ADC circuit 10, according to the present disclosure, may operate at a relatively high speed by performing analog-to-digital conversion based on the TI-ADC 300 including the plurality of ADCs and may sufficiently secure comparison time for each of the plurality of ADCs included in the TI-ADC 300 by rapidly determining the MSB through the flash-ADC 200.

FIG. 8 is a flowchart illustrating an operating method of an ADC circuit, according to an embodiment.

Referring to FIG. 8, the ADC circuit 10, according to the present disclosure, may perform oversampling on a first analog signal corresponding to an input signal to generate a second analog signal in operation S100. The ADC circuit 10, according to the present disclosure, may perform oversampling on the first analog signal based on fed-back N high-order bits (e.g., the MSB described above) to generate the second analog signal.

In operation S200, the second analog signal may be sampled based on a first clock signal having a first sampling frequency, and the sampled second analog signal may be converted from analog to digital to determine N high-order bits, where N is a positive integer greater than or equal to one (1).

In operation S300, the second analog signal may be sampled based on a second clock signal having a second sampling frequency, and the sampled second analog signal may be converted from analog to digital to determine M low-order bits, where M is a positive integer greater than or equal to one (1). The first sampling frequency, which is a sampling frequency of the flash-ADC 200, may be greater than the second sampling frequency, which is a sampling frequency of the TI-ADC 300. Referring to the foregoing, the ADC circuit 10, according to the present disclosure, may include N first capacitors and N first switches each having one end connected to a respective one of the N first capacitors, and configured to switch between a first reference voltage and a second reference voltage. The ADC circuit 10, according to the present disclosure, may switch the N first switches based on the N high-order bits. The ADC circuit 10, according to an embodiment, may further include M second capacitors and M second switches which each have one end connected to a respective one of the M second capacitors, and configured to switch between the first reference voltage and the second reference voltage and may determine M low-order bits based on switching results of the N first switches and a voltage level of a comparison reference node. Here, at least some of the capacitances of the N first capacitors, according to the embodiment, described above may be different from the others, and at least some of the capacitances of the M second capacitors may be different from the others. The largest capacitance among the capacitances of the M second capacitors may be smaller than the smallest capacitance among the capacitances of the N first capacitors.

As described above, the ADC circuit 10 may include K SAR-ADCs operating in a time-interleaving manner. The second sampling frequency may be 2×K times or more the signal band of the input signal.

In operation S400, an output signal including N high-order bits and M low-order bits may be output.

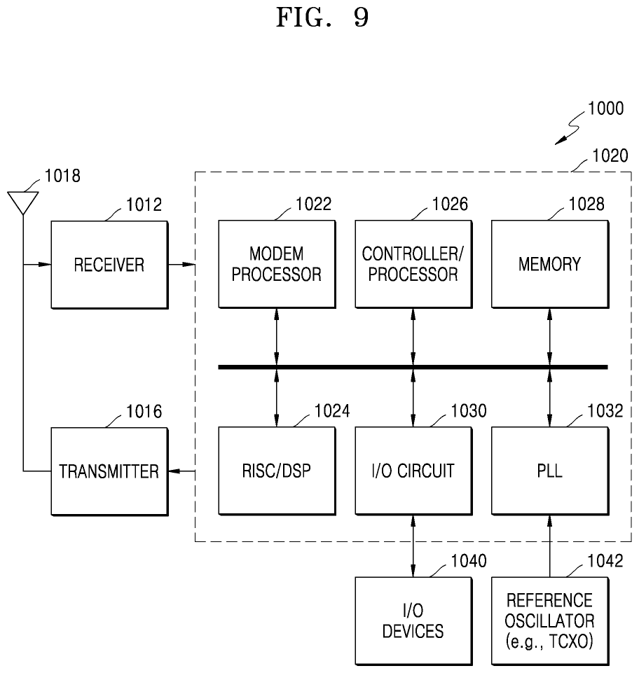

FIG. 9 is a block diagram illustrating a communication device including an ADC circuit, according to an embodiment.

The communication device 1000 of FIG. 9 may include and/or may be similar in many respects to the electronic device 1 described above with reference to FIG. 1, and may include additional features not mentioned above. Consequently, repeated descriptions of the communication device 1000 described above with reference to FIG. 1 may be omitted for the sake of brevity.

Referring to FIG. 9, the communication device 1000 may include a receiver 1012, a transmitter 1016, a communication module 1020, an antenna 1018, an input/output (I/O) device 1040, and a reference oscillator 1042. The receiver 1012 may include the ADC circuit 10 that provides the output signal Dout. The receiver 1012 may convert an analog signal received from the outside through the antenna 1018 into a digital signal using the ADC circuit 10 and provide the digital signal to the communication module 1020. The transmitter 1016 may convert the digital signal received from the communication module 1020 into an analog signal and output the analog signal to the outside through the antenna 1018.

As described above with reference to FIGS. 1 to 5, 6A, 6B, 7, and 8, the ADC circuit 10, according to the present disclosure, may push out spurious components caused by a mismatch of the plurality of ADCs to out-of-band by oversampling the analog signal based on the OSR greater than or equal to the number of ADCs included in the TI-ADC 300. The ADC circuit 10 may perform high-resolution analog-to-digital conversion by removing noise caused by the mismatch of the plurality of ADCs by filtering out-of-band noise (e.g., spurious components). Because the ADC circuit 10, according to the present disclosure, does not require a separate calibration circuit for calibrating the mismatch of the plurality of ADCs, the area and power consumption of the ADC circuit 10 may be reduced. In addition, by performing analog-to-digital conversion based on the TI-ADC 300 including N ADCs, analog-to-digital conversion may be performed at the same speed as that of an ADC that may be N times faster. Each of the N ADCs may be a SAR-ADC, and because the SAR-ADC may need to perform a comparison operation sequentially one by one from the most significant bit to generate a plurality of bits corresponding to the analog signal, and thus, if all of the plurality of bits are determined through the SAR-ADC, the comparison operation may need a potentially excessive amount of time. Because the plurality of ADCs included in the TI-ADC 300, according to the present disclosure, operate in a time-interleaving manner, if the comparison operation takes a significant amount of time, the analog-to-digital conversion may be terminated before the plurality of bits corresponding to the analog signal are determined, resulting in an incomplete analog-to-digital conversion. The ADC circuit 10, according to the present disclosure, may determine at least one high-order bit MSB among the plurality of bits corresponding to the analog signal based on the flash-ADC 200 operating at a relatively high speed. Each of the plurality of ADCs included in the TI-ADC 300 may receive an MSB from the flash-ADC 200 and, based on the MSB, may determine at least one bit LSB of the plurality of bits excluding the MSB. Because each of the plurality of ADCs included in the TI-ADC 300 may determine only the LSB, the time consumed for analog-to-digital conversion in each of the plurality of ADCs may be reduced. That is, the ADC circuit 10, according to the present disclosure, may perform high-speed, high-resolution analog-to-digital conversion. Consequently, as illustrated in FIG. 9, the receiver 1012 requiring high-speed, high-resolution analog-to-digital conversion may include the ADC circuit 10.

The communication module 1020 may include a modem processor 1022, a Reduced Instruction Set Computer (RISC)/Digital Signal Processor (DSP) 1024, a controller/processor 1026, memory 1028, an I/O circuit 1030, and a phase locked loop (PLL) 1032.

The modem processor 1022 may perform processing operations, such as, but not limited to, encoding, modulation, demodulation, and decoding for data transmission and data reception. The RISC/DSP 1024 may perform general and/or specialized processing operations in the communication device 1000. The controller/processor 1026 may control blocks within the communication module 1020. The memory 1028 may store data and/or various command codes. The I/O circuit 1030 may communicate with the external I/O device 1040. The I/O circuit 1030 may convert a data signal received from the external I/O device 1040 into a digital signal using the ADC circuit 10. The PLL 1032 may perform a frequency modulation operation using a frequency signal received from the reference oscillator 1042. The reference oscillator 1042 may be implemented as at least one of a crystal oscillator (XO), a voltage controlled crystal oscillator (VCXO), a temperature-compensated crystal oscillator (TCXO), or the like. The communication module 1020 may perform a processing operation that may be needed for communication using an output signal generated by the PLL 1032.

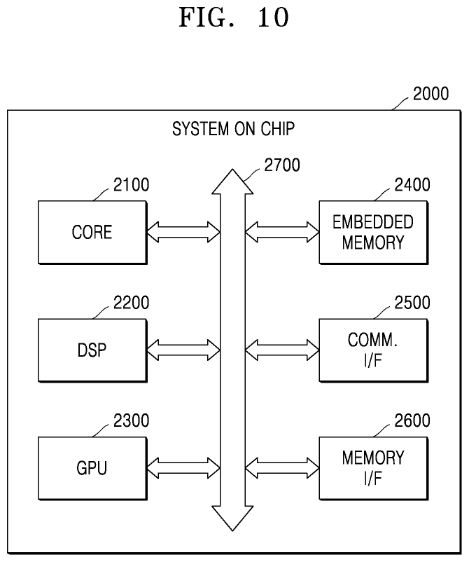

FIG. 10 is a block diagram illustrating a system-on-chip (SoC) 2000 including an ADC circuit, according to an embodiment.

The SoC 2000 of FIG. 10 is described with reference to FIGS. 1 to 5, 6A, 6B, 7, and 8, and any repeated descriptions of the SoC 2000 described above with reference to FIGS. 1 to 5, 6A, 6B, 7, and 8 may be omitted for the sake of brevity.

Referring to FIG. 10, the SoC 2000 may refer to an integrated circuit (IC) in which components of a computing system and/or other electronic systems may be integrated. For example, an application processor (AP) as one of the SOCs 2000 may include components for the processor and other functions.

The SoC 2000 may include a core 2100, a DSP 2200, a graphics processing unit (GPU) 2300, an embedded memory 2400, a communication interface (I/F) 2500, and a memory I/F 2600. Components of the SoC 2000 may communicate with each other via a bus 2700.

The core 2100 may process instructions and/or control the operation of the components included in the SoC 2000. For example, the core 2100 may drive an operating system and execute applications on the operating system by processing a series of instructions. The DSP 2200 may generate data by processing a digital signal, such as, but not limited to, a digital signal provided by the communication I/F 2500. The GPU 2300 may generate data for an image output through a display device from image data provided from the embedded memory 2400 and/or the memory I/F 2600 and/or may encode the image data. The embedded memory 2400 may store data needed by the core 2100, DSP 2200, and/or GPU 2300 to operate. The memory I/F 2600 may provide an interface to an external memory of the SoC 2000, such as, but not limited to, dynamic random access memory (DRAM), flash memory, or the like.

The communication I/F 2500 may provide serial communication with the outside of the SoC 2000. For example, the communication I/F 2500 may be connected to Ethernet and/or may include SerDes for serial communication.

The ADC circuit 10 to which various embodiments of the present disclosure are applied may be applied to the communication I/F 2500 and/or the memory I/F 2600. That is, through the ADC circuit 10 that provides an output signal Dout, the communication I/F 2500 and/or the memory I/F 2600 may receive a data signal based on phase amplitude modulation (PAM), for example, and convert the data signal into digital data, according to embodiments of the present disclosure.

The configuration and operation of the ADC circuit 10, according to the present disclosure, may be sufficiently understood through descriptions given above with reference to FIGS. 1 to 5, 6A, 6B, 7, 8, and 9, and therefore may be omitted for the sake of brevity.

The bus 2700 may operate based on one or more of several bus protocols. For example, the various bus protocols may include, but not be limited to, at least one of advanced microcontroller bus architecture (AMBA) protocol, universal serial bus (USB) protocol, multimedia card (MMC) protocol, peripheral component interconnect (PCI) protocol, PCI-express (PCI-E) protocol, advanced technology attachment (ATA) protocol, serial-ATA protocol, parallel-ATA protocol, small computer small interface (SCSI) protocol, enhanced small disk interface (ESDI) protocol, integrated drive electronics (IDE) protocol, mobile industry processor interface (MIPI) protocol, universal flash storage (UFS) protocol, or the like.

The ADC circuit 10, according to the present disclosure, may be applied to various technical fields that may need relatively high-speed and/or relatively high-resolution ADC conversion in addition to the technical fields described above. For example, the ADC circuit 10 may be applied to military systems, aviation systems, radar systems, or the like for tracking high-speed moving objects, as well as, to medical imaging fields that may need a relatively high resolution.

While the present disclosure has been particularly shown and described with reference to embodiments thereof, it is to be understood that various changes in form and/or details may be made therein without departing from the spirit and scope of the following claims.

What is claimed is:

1. An analog-to-digital conversion circuit configured to perform analog-to-digital conversion on an input signal to generate an output signal, the analog-to-digital conversion circuit comprising:
a loop filter configured to perform oversampling on a first analog signal corresponding to the input signal to generate a second analog signal;
a flash-analog-to-digital converter (flash-ADC) configured to:
sample the second analog signal based on a first clock signal having a first sampling frequency, and
determine N high-order bits from among a plurality of bits corresponding to the sampled second analog signal; and
a first successive approximation register-ADC (SAR-ADC) configured to:
sample the second analog signal based on a second clock signal having a second sampling frequency, and
determine M low-order bits corresponding to remaining bits excluding the N high-order bits from among the plurality of bits corresponding to the sampled second analog signal,
wherein the output signal corresponding to the first analog signal is generated based on the N high-order bits and the M low-order bits,
wherein N is a first positive integer greater than or equal to 1, and
wherein M is a second positive integer greater than or equal to 1.

2. The analog-to-digital conversion circuit of claim 1, wherein the first SAR-ADC comprises N switches, and
wherein the first SAR-ADC is further configured to control the N switches based on the N high-order bits.

3. The analog-to-digital conversion circuit of claim 2, wherein the N switches are respectively coupled with N capacitors from among a plurality of capacitors,
wherein a capacitance of each of the N capacitors is greater than a capacitance of each of remaining capacitors excluding the N capacitors from among the plurality of capacitors, and
wherein the N capacitors are coupled with a comparison reference node of the first SAR-ADC.

4. The analog-to-digital conversion circuit of claim 3, wherein the first SAR-ADC further comprises M switches respectively coupled with M capacitors excluding the N capacitors from among the plurality of capacitors, and
wherein the first SAR-ADC is further configured to determine the M low-order bits by controlling the M switches.

5. The analog-to-digital conversion circuit of claim 1, further comprising:
a plurality of SAR-ADCs comprising the first SAR-ADC,
wherein the second sampling frequency is greater than or equal to 2×K times a signal band of the input signal, and
wherein K is equal to a number of SAR-ADCs comprised in the plurality of SAR-ADCs.

6. The analog-to-digital conversion circuit of claim 1, wherein the loop filter is further configured to:
perform oversampling on the first analog signal based on the N high-order bits fed back from the flash-ADC.

7. The analog-to-digital conversion circuit of claim 1, further comprising:
at least one SAR-ADC,
wherein the first SAR-ADC and the at least one SAR-ADC operate sequentially in a time-interleaving manner.

8. The analog-to-digital conversion circuit of claim 1, wherein the first sampling frequency is higher than the second sampling frequency.

9. An operating method of an analog-to-digital conversion circuit for performing analog-to-digital conversion on an input analog signal to generate an output digital signal, the operating method comprising:
performing oversampling on a first analog signal corresponding to the input analog signal to generate a second analog signal;
sampling the second analog signal based on a first clock signal having a first sampling frequency;
determining N high-order bits by performing the analog-to-digital conversion on the sampled second analog signal;
sampling the second analog signal based on a second clock signal having a second sampling frequency;
determining M low-order bits by performing the analog-to-digital conversion on the sampled second analog signal; and
outputting the output digital signal comprising the N high-order bits and the M low-order bits,
wherein N is a first positive integer greater than or equal to 1, and
wherein M is a second positive integer greater than or equal to 1.

10. The operating method of claim 9, wherein the determining of the M low-order bits comprises:
controlling N first switches to switch between a first reference voltage and a second reference voltage, based on the N high-order bits, and
wherein the N first switches are respectively coupled with N first capacitors of a plurality of capacitors.

11. The operating method of claim 10, wherein the determining of the M low-order bits further comprises:
sequentially controlling M second switches to switch between the first reference voltage and the second reference voltage, based on a control result of the N first switches and a voltage level of a comparison reference node, and
wherein the M second switches are respectively coupled with M second capacitors excluding the N first capacitors from among the plurality of capacitors.

12. The operating method of claim 11, wherein a first capacitance of at least one first capacitor of the N first capacitors is different from first capacitances of first remaining capacitors excluding the at least one first capacitor from among the N first capacitors,
wherein a second capacitance of at least one second capacitor of the M second capacitors is different from second capacitances of second remaining capacitors excluding the at least one second capacitor from among the M second capacitors, and
wherein a maximum capacitance from among the second capacitances of the M second capacitors is smaller than a minimum capacitance from among the first capacitances of the N first capacitors.

13. The operating method of claim 9, wherein the sampling of the second analog signal based on the second clock signal comprises:
sampling the second analog signal based on the second clock signal having the second sampling frequency that is greater than or equal to 2×K times a signal band of the input analog signal, and
wherein K is equal to a number of successive approximation register-analog-to-digital converters (SAR-ADCs) comprised in the analog-to-digital conversion circuit.

14. The operating method of claim 9, wherein the generating of the second analog signal comprises:
generating the second analog signal by performing the oversampling on the first analog signal based on the N high-order bits that are fed back.

15. The operating method of claim 9, wherein the first sampling frequency is higher than the second sampling frequency.

16. The operating method of claim 13, further comprising:
operating the SAR-ADCs in a time interleaved manner.

17. An electronic device for performing analog-to-digital conversion on an input signal to generate an output signal, the electronic device comprising:
a clock signal generation circuit configured to generate a first clock signal having a first sampling frequency and a second clock signal having a second sampling frequency; and
an analog-to-digital conversion circuit configured to:
perform oversampling on a first analog signal corresponding to the input signal to generate a second analog signal,
sample the second analog signal based on the first clock signal,
determine N high-order bits corresponding to the second analog signal in a flash-analog-to-digital conversion manner,
sample the second analog signal based on the second clock signal,
determine M low-order bits corresponding to the second analog signal in a successive approximation register-analog-to-digital conversion (SAR-ADC) manner, wherein the analog-to-digital conversion circuit comprises:
a plurality of capacitors comprising N first capacitors and M second capacitors;
N first switches coupled with a respective first capacitor of the N first capacitors, and configured to switch between a first reference voltage and a second reference voltage; and
M second switches coupled with a respective second capacitor of the M second capacitors, and configured to switch between the first reference voltage and the second reference voltage,
wherein the analog-to-digital conversion circuit is further configured to determine the M low-order bits in the SAR-ADC manner based on the M second capacitors and the M second switches after the N first switches are switched based on the N high-order bits,
wherein N is a first positive integer greater than or equal to 1, and
wherein M is a second positive integer greater than or equal to 1.

18. The electronic device of claim 17, wherein the analog-to-digital conversion circuit further comprises a plurality of SAR-ADCs,
wherein the second sampling frequency is greater than or equal to 2×K times a signal band of the input signal, and
wherein K is equal to a number of SAR-ADCs comprised in the plurality of SAR-ADCs.

19. The electronic device of claim 17, wherein the first sampling frequency is higher than the second sampling frequency.

20. The electronic device of claim 17, wherein a first capacitance of at least one first capacitor of the N first capacitors is different from first capacitances of first remaining capacitors excluding the at least one first capacitor from among the N first capacitors,
wherein a second capacitance of at least one second capacitor of the M second capacitors is different from second capacitances of second remaining capacitors excluding the at least one second capacitor from among the M second capacitors, and
wherein a maximum capacitance from among the second capacitances of the M second capacitors is smaller than a minimum capacitance from among the first capacitances of the N first capacitors.
